(19) United States
(12) Patent Application Publication
(10) Pub. No.: US 2024/0096599 A1
(43) Pub. Date: Mar. 21, 2024

(54) PLASMA PROCESSING DEVICE

(71) Applicant: Hitachi High-Tech Corporation, Minato-ku, Tokyo (JP)

(72) Inventors: Koichi Takasaki, Tokyo (JP); Taku Iwase, Tokyo (JP)

(73) Assignee: Hitachi High-Tech Corporation, Minato-ku, Tokyo (JP)

(21) Appl. No.: 17/641,538

(22) PCT Filed: Feb. 8, 2021
(86) PCT No.: PCT/JP2021/004592

§ 371 Date: Dec. 8, 2023

(51) Int. Cl. H01J 37/32

(52) U.S. Cl. CPC H01J 37/32174; H01J 37/32651; H01J 37/3266; H01J 37/32715; H01J 2237/3345

(57) ABSTRACT

In order to execute stable processing by suppressing plasma diffusion and non-stationary discharge generation, there is provided a plasma processing device which includes a processing chamber in which a sample stage is provided for placing a sample thereon, an exhaust unit for evacuating the processing chamber, a magnetic field forming mechanism for forming a magnetic field in the processing chamber, and a power supply unit that supplies radio frequency power for generating plasma to the inside of the processing chamber evacuated by the exhaust unit and has the magnetic field formed by the magnetic field forming mechanism. The processing chamber includes a shielding section which divides an inner part of the processing chamber into a first area at a side for supplying the radio frequency power from the power supply unit and a second area at a side where the sample stage is disposed. The shielding section includes a first shielding plate disposed at the side that faces the first area, in which a first opening is formed, a second shielding plate disposed at the side that faces the second area, in which a second opening is formed at the center, and a third shielding plate disposed between the first and the second shielding plates.

### TECHNICAL FIELD

The present invention relates to a plasma processing device.

### BACKGROUND ART

Responding to an increasing market demand for power-saving and acceleration of operation speeds of a semiconductor device, the device structure has been likely to be complicated and highly integrated remarkably. For example, in the case of a logic device, application of FET to GAA (Gate All Around) structure of channeling using laminated nanowire or nanosheet has been under consideration. The etching process of GAA-FET requires isotropic processing for forming the nanowire or the nanosheet in addition to the vertical processing for forming Fin.

Manufacturing of the semiconductor device is demanded to cope with the above-described complication of the semiconductor device. In the case of processing the GAA-FET, the plasma etching device used for processing the semiconductor device is required to implement functions of anisotropic etching by emitting both ions and radicals, and isotropic etching by emitting only neutral particles such as radicals.

As proposed in PTL 1, the shielding plate for shielding incidence of ions is placed in the chamber. Plasma is generated below the shielding plate to execute plasma processing by emitting both ions and radicals, or plasma is generated above the shielding plate to execute the processing using only radicals.

As disclosed in PTL 2, two or more plates each having multiple through openings are disposed so as not to overlap with one another for shielding ions in plasma, and for selectively allowing passage of radicals.

### CITATION LIST

### Patent Literature

PTL 1: Japanese Patent Application Laid-Open No. 2018-93226
PTL 2: Japanese Patent Application Laid-Open No. 2006-86449

### SUMMARY OF INVENTION

### Technical Problem

In the case of the plasma processing device as disclosed in PTL 1, although plasma is required to be generated only below the shielding section, the plasma will diffuse upward above the shielding section depending on the plasma generation condition. The diffused plasma may become unstable to cause non-stationary discharge generation above the shielding section unexpectedly. Although plasma is required to be generated only above the shielding section, the plasma will diffuse downward below the shielding section depending on the plasma generation condition. The diffused plasma below the shielding section may become unstable to cause non-stationary discharge generation below the shielding section unexpectedly. In the circumstances, even if the processing is required to be executed by emitting only radicals, the plasma generated below the shielding section may cause ions to be emitted to the sample from the plasma generated below the shielding section.

In the case of the plasma processing device as disclosed in PTL 2, two or more plates each having multiple through holes are disposed so as not to overlap with one another for shielding ions in plasma, and for selectively allowing passage of radicals. Shielding of ions may be insufficient to suppress plasma diffusion and generation of non-stationary discharge.

In order to solve the above-described problem, it is an object of the present invention to provide the plasma processing device for stable processing by suppressing plasma diffusion and generation of non-stationary discharge.

### Solution to Problem

In order to solve the above-described problem, the present invention provides the plasma processing device including a processing chamber in which a sample is plasma processed, a radio frequency power supply for supplying microwave radio frequency power, a magnetic field forming mechanism for forming a magnetic field in the processing chamber, a sample stage on which the sample is placed, a first shielding plate for shielding an ion, and a second shielding plate disposed below the first shielding plate for shielding the ion. The plasma processing device further includes a shielding unit disposed between the first shielding plate having a first opening and the second shielding plate having a second opening. The shielding unit is located to shield a line that passes through the first opening and the second opening.

### Advantageous Effects of Invention

The plasma processing device according to the present invention improves the ion shielding effect between the first area and the second area in the processing chamber so that unexpected generation of discharge can be suppressed. This makes it possible to execute stable plasma processing to the substrate to be processed.

### BRIEF DESCRIPTION OF DRAWINGS

FIG. 1 It is a front sectional view schematically illustrating an overall structure of a plasma processing device according to Example 1.

FIG. 2A It is a detailed front sectional view illustrating a structure of a shielding section of the plasma processing device according to Example 1.

FIG. 2B It is a plan view of a first shielding plate constituting the shielding section according to Example 1.

FIG. 2C It is a plan view of a third shielding section constituting the shielding section according to Example 1.

FIG. 2D It is a plan view of a second shielding section constituting the shielding section according to Example 1.

FIG. 3A It is a detailed front sectional view illustrating a structure of a shielding section of a plasma processing device according to Example 2.

FIG. 3B It is a plan view of a first shielding plate constituting the shielding section according to Example 2.

FIG. 3C It is a plan view of a third shielding section constituting the shielding section according to the example.

FIG. 4A It is a detailed front sectional view of a structure of a shielding section of a plasma processing device according to Example 3.

FIG. 4B It is a plan view of a third shielding section constituting the shielding section according to Example 3.

FIG. 4C It is a plan view of a second shielding section constituting the shielding section according to Example 3.

FIG. 5 It is a detailed front sectional view illustrating a structure of a shielding section of a plasma processing device according to Example 4.

FIG. 6A It is a detailed front sectional view illustrating a structure of a shielding section of a plasma processing device according to Example 5.

FIG. 6B It is a plan view of a third shielding section constituting the shielding section according to Example 5.

FIG. 6C It is a plan view of a second shielding section constituting the shielding section according to Example 5.

FIG. 7 It is a detailed front sectional view illustrating a structure of a shielding section of a plasma processing device according to Example 6.

FIG. 8 It is a detailed front sectional view illustrating a structure of a shielding section of a plasma processing device according to Example 7.

FIG. 9 It is a detailed front sectional view illustrating a structure of a shielding section of a plasma processing device according to Example 8.

FIG. 10A It is a graph indicating a stable Ar plasma region in a plasma processing device as a comparative example of Example 1.

FIG. 10B It is a graph indicating the stable Ar plasma region in the plasma processing device according to Example 1.

### DESCRIPTION OF EMBODIMENT

A plasma processing device according to the present invention includes a processing chamber in which a sample is plasma processed, a radio frequency power supply for supplying microwave radio frequency power to generate plasma in the processing chamber, a magnetic field forming mechanism for forming the magnetic field in the processing chamber, a sample stage on which the sample is placed, a first shielding section for shielding incidence of ions to the sample stage, and a second shielding plate disposed below the first shielding section for shielding incidence of ions to the sample stage. The first shielding plate includes one or more first openings, and the second shielding plate includes one or more second openings. A third shielding plate disposed between the first and the second shielding plates shields a line formed by connection between an arbitrary point in a first space above the first shielding plate in the processing chamber and an arbitrary point in a second space below the second shielding plate in the processing chamber through the first and the second openings. The above structure suppresses diffusion of plasma between the first and the second spaces in the processing chamber to improve ion shielding effects.

The embodiment of the present invention will be described referring to the drawings. In the specification, the term “above” denotes the “location closer to the power supply unit”, for example, magnetron, and the term “below” denotes the “location closer to the sample stage inside the processing chamber”. The term “during isotropic etching” denotes “during execution of etching that mainly involves sample surface reaction by radicals”.

In all the drawings for explaining the embodiment, components with the same functions will be designated with the same codes, and basically, repetitive explanations will be omitted.

The present invention should not be interpreted with respect only to the content of the embodiment as described below in an attributive manner. It is to be easily understood for those who are ordinary skill in the art that the specific structure can be variously modified without departing from the idea and spirit of the present invention.

### Example 1

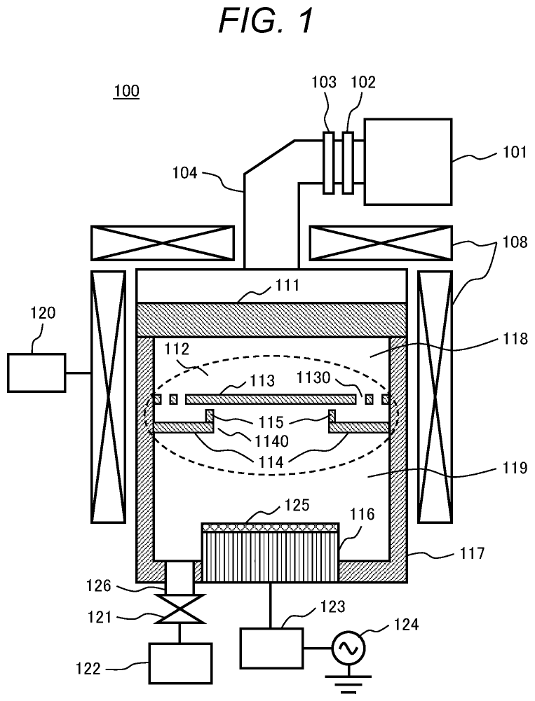

FIG. 1 is a front sectional view schematically illustrating an overall structure of a plasma processing device 100 according to Example 1 of the present invention. The plasma processing device 100 of the example allows generation of plasma in a vacuum processing chamber 117 by electron cyclotron resonance between microwave at 2.45 GHz oscillated from a magnetron 101 as the radio frequency power supply, and supplied to the vacuum processing chamber 117 via an isolator 102, an automatic matching unit 103, a waveguide 104, and a dielectric window 111, and the magnetic field generated by a solenoid coil 108 as a magnetic field forming mechanism. The plasma processing device will be referred to as an ECR plasma processing device.

A sample 125 placed on a sample stage 116 is connected to a radio frequency power supply 124 via a matching unit 123. An inner part of the vacuum processing chamber 117 is connected to a pump 122 from an exhaust port 126 via a valve 121 so that the internal pressure of the vacuum processing chamber 117 can be adjusted in accordance with an opening degree of the valve 121.

The plasma processing device 100 includes a dielectric shielding section (shielding unit) 112 in the vacuum processing chamber 117. The shielding section 112 serves to divide the inner part of the vacuum processing chamber 117 into a first area 118 and a second area 119.

Assuming that the frequency of the microwave oscillated by the magnetron 101 and supplied to the vacuum processing chamber 117 via the isolator 102, the automatic matching unit 103, and the waveguide 104 is 2.45 GHz, the plasma processing device 100 used for the embodiment is allowed to generate plasma by the electron cyclotron resonance (ECR) which occurs around the plane of the magnetic field with intensity of 0.0875 T, which is generated by the solenoid coil 108.

Adjustment of the magnetic field generated by the solenoid coil 108 to have the plasma generation region positioned between the shielding section 112 and the dielectric window 111 (first area 118) allows generation of plasma in the first area 118 at the side of the dielectric window 111 above the shielding section 112.

The magnetic field restricts movement of ions generated in the first area 118, and hardly allows passage of the ions through the shielding section 112. Meanwhile, the magnetic field does not restrict radicals so that only radicals in the plasma generated in the first area 118 are supplied to the second area 119.

In the second area 119, the radicals are emitted onto the sample 125 to undergo the isotropic etching that mainly involves the surface reaction only by the radicals.

Adjustment of the magnetic field generated by the solenoid coil 108 to have the plasma generation region positioned between the shielding section 112 and the sample 125 (second area 119) allows generation of plasma in the second area 119 at the side of the sample 125 placed on the sample stage 116 below the shielding section 112.

As plasma is generated in the second area 119, both ions and radicals generated in the plasma can be supplied to the sample 125. In this case, anisotropic etching to the sample 125 proceeds utilizing ion-assisted reaction for promoting radical reaction by ions.

Selection of the plasma generation region, adjustment of position of the plasma generation region in each area in the height direction (up-down direction of FIG. 1), and adjustment of the period for holding the height position of the plasma generation region in each area between the first area 118 above the shielding section 112 and the second area 119 below the shielding section 112 can be executed by controlling the position at which the magnetic field intensity becomes 0.0875 T through adjustment of the magnetic field generated by the solenoid coil 108 using a control unit 120.

The shielding section 112 includes a first shielding plate 113, a second shielding plate 114, and a third shielding plate 115. The first shielding plate 113 includes one or more openings 1130. The second shielding plate 114 also includes one or more openings 1140, and is disposed below the first shielding plate 113 (at the side closer to the second area 119).

The third shielding plate 115 formed into a cylindrical shape is disposed between the first shielding plate 113 and the second shielding plate 114 to shield a line formed by connecting an arbitrary point in the first area 118 above the first shielding plate 113 (at the side of dielectric window 111) and an arbitrary point in the second area 119 through the opening 1130 of the first shielding plate 113 and the opening 1140 of the second shielding plate 114.

The third shielding plate 115 serves to adjust the magnetic field generated by the solenoid coil 108 under the control of the control unit 120 to suppress diffusion of plasma generated in the first area 118 to the second area 119. This improves the ion shielding effects to suppress generation of non-stationary plasma in the second area 119. It is possible to execute the etching process to the sample 125 uniformly and stably.

In the case where there is no height position adjustment mechanism of the plasma generation region formed by combining the control unit 120 and the solenoid coil 108, provision of the shielding section 112 of the example is expected to provide the effect similar to the one derived from the general plasma processing device configured to generate plasma above the shielding section 112, and to attempt the etching only by radicals.

In the case where plasma is generated in the second area 119, the shielding section 112 provided with the third shielding plate 115 of the example allows suppression of plasma diffusion from the second area 119 to the first area 118. This makes it possible to execute the etching process to the sample 125 uniformly and stably by suppressing non-stationary discharge generation in the first area 118 starting from the diffused plasma.

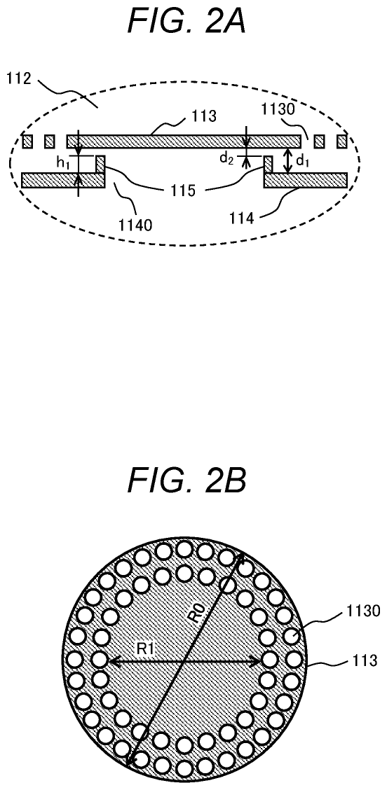

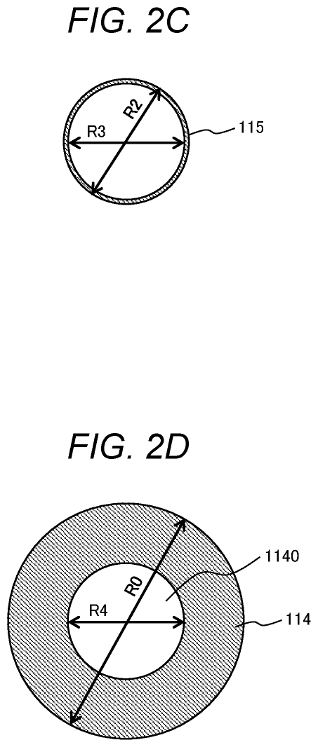

FIGS. 2A to 2D illustrate the structure of the shielding section 112 according to the example. FIG. 2A is a front sectional view of the shielding section 112. FIG. 2B is a plan view of the first shielding plate 113. FIG. 2C is a plan view of the second shielding plate 114. FIG. 2D is a plan view of the third shielding plate 115.

As FIG. 2A illustrates, the shielding section 112 of the example includes the first shielding plate 113, the second shielding plate 114, and the third shielding plate 115.

As FIG. 2B illustrates, the first shielding plate 113 has a disc-like shape with external diameter of R0, and one or more openings 1130 formed in an outer circumferential area with diameter larger than R1. As FIG. 2D illustrates, the second shielding plate 114 has a disc-like shape with the same external diameter of R0 as that of the first shielding plate 113, and an opening 1140 with diameter of R4, which is formed at the center. As FIG. 2D illustrates, the third shielding plate 115 has a cylindrical shape with external diameter of R2 and internal diameter of R3. As FIG. 2A illustrates, a height h₁ of the cylinder is lower than a distance d₁ between the first shielding plate 113 and the second shielding plate 114. In the state where the third shielding plate 115 is mounted on the second shielding plate 114, a gap d₂ is formed from the first shielding plate 113.

A relation among the diameters of R0>R1>R2>R3>R4 is obtained, where R0 denotes each external diameter of the first shielding plate 113 and the second shielding plate 114, R1 denotes a diameter of a region of the shielding plate 113 at the center, in which no openings are formed, R2, R3 denote an external diameter and an internal diameter of the cylinder of the third shielding plate 115, respectively, and R4 denotes a diameter of the opening 1140 of the second shielding plate 114.

It is assumed that the R0 is set to 450 mm, the R1 is set to 320 mm, the R2 is set to 284 mm, the R3 is set to 280 mm, the R4 is set to 280 mm, the distance d₁ between the first shielding plate 113 and the second shielding plate 114 is set to 30 mm, and the height h₁ of the inner cylinder of the third shielding plate 115 is set to 20 mm.

The first shielding plate 113 and the second shielding plate 114 each having the external diameter R0 are held at points of contact with the vacuum processing chamber 117. The third shielding plate 115 is mounted on the second shielding plate 114. Alternatively, the third shielding plate 115 may be integrally formed with the second shielding plate 114.

In the structure constituted by the first shielding plate 113, the second shielding plate 114, and the third shielding plate 115, the third shielding plate 115 is located to cross an arbitrary line formed by connecting the first area 118 above the first shielding plate 113 and the second area 119 below the second shielding plate 114 through the opening 1130 formed in the first shielding plate 113 and the opening 1140 formed in the second shielding plate 114. This makes it possible to prevent the plasma diffusion between the first area 118 and the second area 119.

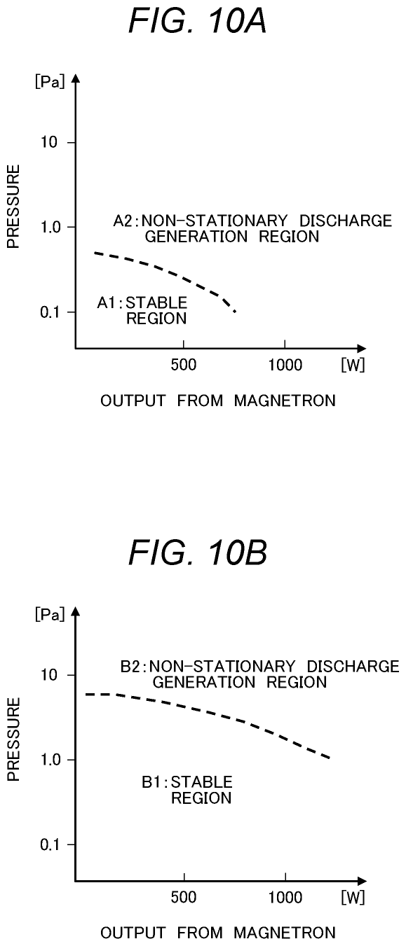

FIGS. 10A and 10B represent an effect derived from the structure of the shielding section without using the third shielding plate 115 as illustrated in FIG. 2C, and an effect derived from the structure of the shielding section 112 using the third shielding plate 115 as illustrated in FIG. 2A, which is constituted by the components as illustrated in FIGS. 2B to 2D, respectively for the purpose of comparison.

FIG. 10A represents an Ar gas discharge state in the vacuum processing chamber 117 when using the shielding section without the third shielding plate 115 as illustrated in FIG. 2C as a comparative example of the present example. Referring to the graph shown in FIG. 10A, X-axis denotes an output from the magnetron 101, and Y-axis denotes the internal pressure of the vacuum processing chamber 117. Codes A1 and A2 in the graph denote the stable discharge region, and the non-stationary discharge generation region, respectively.

The region A2 where the non-stationary discharge is generated indicates the region where non-stationary discharge is generated in the first area 118 depending on the internal pressure of the vacuum processing chamber 117 and the output from the magnetron 101 under the condition for generating plasma in the second area 119 inside the vacuum processing chamber 117. In the comparative example, the region A1 in the stable discharge state is relatively narrow.

FIG. 10B represents an Ar gas discharge state in the case of the shielding section 112 as illustrated in FIG. 2A of the example, that is, using the third shielding plate 115. Referring to the graph shown in FIG. 10B, X-axis denotes the output from the magnetron 101, and Y-axis denotes the internal pressure of the vacuum processing chamber 117. Codes B1, B2 in the graph indicate the stable discharge region, and the non-stationary discharge generation region, respectively.

The stable discharge region B1 in FIG. 10B is enlarged in comparison with the stable discharge region A1 of FIG. 10A. The non-stationary discharge region B2 in FIG. 10B is reduced in comparison with the non-stationary discharge generation region A2 in FIG. 10A. That is, the use of the shielding section 112 including the third shielding plate 115 according to the example makes it possible to enlarge the stable discharge region B1 compared with the use of the shielding section without the third shielding plate 115.

By providing the third shielding plate 115 in this way, upon discharge under the condition for generating plasma in the second area 119 inside the vacuum processing chamber 117, the third shielding plate 115 suppresses diffusion of plasma from the second area 119 to the first area 118. As a result, generation of non-stationary discharge in the first area 118 is suppressed to significantly enlarge the stable plasma forming region in the second area 119.

Thus, the stable plasma forming region is significantly enlarged in the second area 119 so that both ions and radicals can be supplied to the sample 125. This allows stable execution of anisotropic etching to the sample 125 utilizing the ion-assisted reaction for promoting radical reaction by ions.

Upon discharge under the condition for generating plasma in the first area 118 inside the vacuum processing chamber 117, the third shielding plate 115 suppresses diffusion of plasma from the first area 118 to the second area 119. As a result, generation of non-stationary discharge in the second area 119 is suppressed to significantly enlarge the stable plasma forming region in the first area 118.

The stable plasma is formed in the first area, and only radicals from plasma generated in the first area 118 are supplied to the second area 119. As a result, radicals are only emitted to the sample 125 in the second area to allow execution of the isotropic etching that mainly involves the radical surface reaction of the sample 125.

In the above-described example, the shielding section 112 includes the third shielding plate 115 to suppress diffusion of plasma from the second area 119 to the first area 118, or from the first area 118 to the second area 119 so that generation of the non-stationary discharge in the first area 118 or the second area 119 can be suppressed. This makes it possible to stably execute the anisotropic etching and isotropic etching to the sample 125 in the state where the unexpected discharge generation is suppressed in the second area 119.

### Example 2

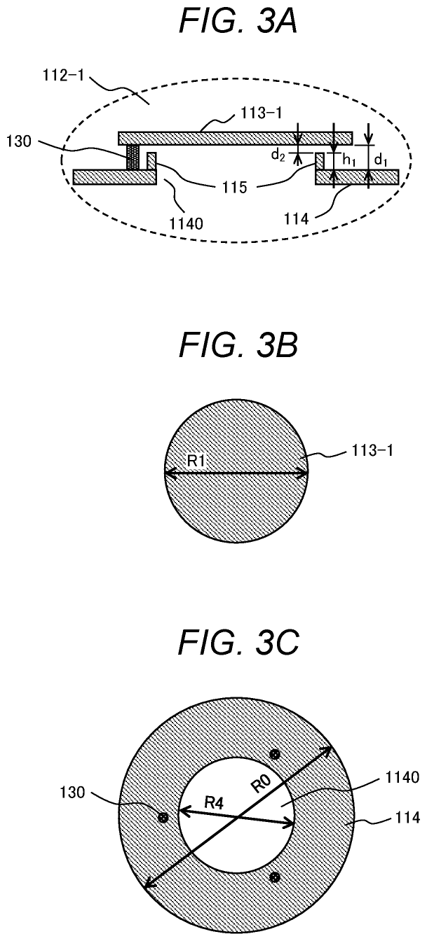

FIG. 3A is a front view representing an example of a shielding section 112-1 according to a second embodiment of the present invention. Structures except the shielding section 112-1 are the same as those described in Example 1 referring to FIG. 1, and explanations thereof, thus will be omitted.

The second shielding plate 114 of the shielding section 112-1 as illustrated in FIG. 3C has a disc-like shape and the opening 1140 formed at the center similar to Example 1. A first shielding plate 113-1 as illustrated in FIG. 3B has a disc-like shape with diameter R1 smaller than the internal diameter of the vacuum processing chamber 117. A gap formed between the first shielding plate 113-1 and the wall surface of the vacuum processing chamber 117 forms an opening. The first shielding plate 113-1 is held by three or more dielectric holders 130 disposed on the second shielding plate 114 as illustrated in FIG. 3C. The third shielding plate 115 having a cylindrical shape like the one as described in Example 1 is mounted on the second shielding plate 114. The third shielding plate has the cylinder height h₁ lower than the distance d₁ between the first shielding plate 113-1 and the second shielding plate 114, and a gap d₂ formed from the first shielding plate 133-1.

In the shielding section 112-1 structured as illustrated in FIGS. 3A to 3C, the third shielding plate 115 is located to cross the arbitrary line formed by connecting the first area 118 above the first shielding plate 113-1 and the second area 119 below the second shielding plate 114 through an opening formed between an outer circumference of the first shielding plate 113-1 and the wall surface of the vacuum processing chamber 117, and the opening 1140 formed in the second shielding plate 114 similar to Example 1 as described above. This makes it possible to prevent diffusion of plasma between the first area 118 and the second area 119.

Upon discharge under the condition for generating plasma in the second area 119 inside the vacuum processing chamber 117, the third shielding plate 115 suppresses diffusion of plasma from the second area 119 to the first area 118. Similarly to the case of Example 1, the stable plasma forming region is significantly enlarged in the second area 119.

The stable plasma forming region is significantly enlarged in the second area 119 so that both ions and radicals can be supplied to the sample 125. This allows stable execution of anisotropic etching to the sample 125 utilizing the ion-assisted reaction for promoting radical reaction by ions.

Meanwhile, upon discharge under the condition for generating plasma in the first area 118 inside the vacuum processing chamber 117, the third shielding plate 115 suppresses diffusion of plasma from the first area 118 to the second area 119. As a result, generation of non-stationary discharge in the second area 119 is suppressed to significantly enlarge the stable plasma forming region in the first area 118.

The stable plasma is formed in the first area, and only radicals from plasma generated in the first area 118 are supplied to the second area 119. As a result, radicals are only emitted to the sample 125 in the second area 119 to allow execution of the isotropic etching that mainly involves the radical surface reaction of the sample 125.

Similarly to the explanation in Example 1, in the example, the shielding section 112-1 includes the third shielding plate 115 to suppress diffusion of plasma from the second area 119 to the first area 118, or from the first area 118 to the second area 119 so that generation of the non-stationary discharge in the first area 118 or the second area 119 can be suppressed. This makes it possible to stably execute the anisotropic etching and isotropic etching to the sample 125 in the state where the unexpected discharge generation is suppressed in the second area 119.

### Example 3

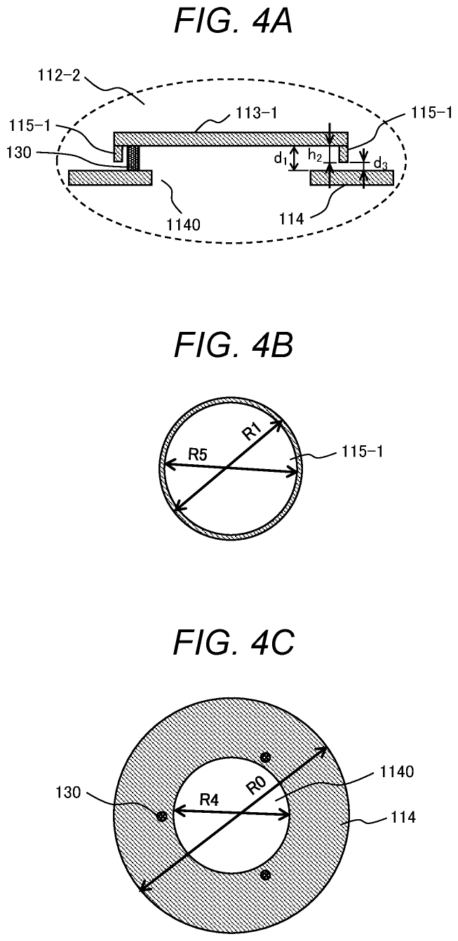

FIG. 4A is a front view representing an example of a shielding section 112-2 according to Example 3 of the present invention. Structures except the shielding section 112-2 are the same as those described in Example 1 referring to FIG. 1, and explanations thereof will be omitted.

The second shielding plate 114 as illustrated in FIG. 4C has the disc-like shape and the opening 1140 formed at the center, and held at a point contact with the vacuum processing chamber 117. A first shielding plate 113-1 as illustrated in FIG. 4A has a disc-like shape, and the external diameter that is the same as the diameter R1 of a third shielding plate 115-1 as illustrated in FIG. 4B. The diameter R1 is smaller than the internal diameter of the vacuum processing chamber 117 so that the gap from the wall surface of the vacuum processing chamber 117 is formed as an opening. The first shielding plate 113-1 is held by three or more dielectric holders 130 disposed on the second shielding plate 114 as illustrated in FIG. 4C.

As illustrated in FIG. 4B, the third shielding plate 115-1 has a cylindrical shape with internal diameter R1, and external diameter R5, and is integrally formed with the first shielding plate 113-1. A height h₂ of the cylinder of the third shielding plate 115-1 is shorter than the distance d₁ between the first shielding plate 113-1 and the second shielding plate 114. The third shielding plate 115-1 is disposed above the second shielding plate 114 to form a gap d₃ therebetween.

In the shielding section 112-2 structured as illustrated in FIGS. 4A to 4C, the third shielding plate 115-1 is located to cross the arbitrary line formed by connecting the first area 118 above the first shielding plate 113-1 and the second area 119 below the second shielding plate 114 through the opening formed between the outer circumference of the first shielding plate 113-1 and the wall surface of the vacuum processing chamber 117, and the opening 1140 formed in the second shielding plate 114 similar to Example 1 as described above. This makes it possible to prevent diffusion of plasma between the first area 118 and the second area 119.

Upon discharge under the condition for generating plasma in the second area 119 inside the vacuum processing chamber 117, the third shielding plate 115-1 suppresses diffusion of plasma from the second area 119 to the first area 118. As a result, generation of non-stationary discharge in the first area 118 is suppressed to significantly enlarge the stable plasma forming region in the second area 119.

The stable plasma forming region is significantly enlarged in the second area 119 so that both ions and radicals can be supplied to the sample 125. This allows stable execution of anisotropic etching to the sample 125 utilizing the ion-assisted reaction for promoting radical reaction by ions.

Meanwhile, upon discharge under the condition for generating plasma in the first area 118 inside the vacuum processing chamber 117, the third shielding plate 115-1 suppresses diffusion of plasma from the first area 118 to the second area 119. As a result, generation of non-stationary discharge in the second area 119 is suppressed to significantly enlarge the stable plasma forming region in the first area 118.

The stable plasma is formed in the first area, and only radicals from plasma generated in the first area 118 are supplied to the second area 119. As a result, only radicals are emitted to the sample 125 in the second area to allow execution of the isotropic etching that mainly involves the radical surface reaction of the sample 125.

Similarly to the explanation in Example 1, in the example, the shielding section 112-2 includes the third shielding plate 115-1 to suppress diffusion of plasma from the second area 119 to the first area 118, or from the first area 118 to the second area 119 so that generation of the non-stationary discharge in the first area 118 or the second area 119 can be suppressed. This makes it possible to stably execute the anisotropic etching and isotropic etching to the sample 125 in the state where the unexpected discharge generation is suppressed in the second area.

### Example 4

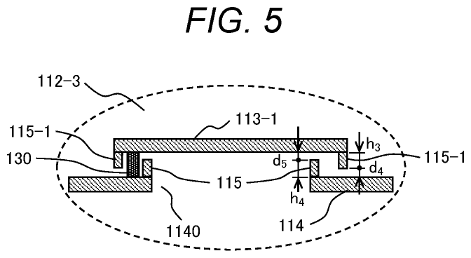

FIG. 5 is a plan view representing an example of a shielding section 112-3 according to Example 4 of the present invention. Structures of the example except the shielding section 112-3 are the same as those described in Example 1 referring to FIG. 1, and explanations thereof, thus will be omitted.

The structure of the shielding section 112-3 of the example is formed by combining the shielding section 112-1 as described in Example 2, and the shielding section 112-2 as described in Example 3. That is, the third shielding plate of the example is formed by combining the shielding plate 115 as described in Example 2 and the shielding plate 115-1 as described in Example 3.

The second shielding plate 114 is the same as the one which has been described in Example 3 referring to FIG. 4C. The second shielding plate has the disc-like shape and the opening 1140 formed at the center, the outer circumference of which is held at a point contact with the vacuum processing chamber 117. The first shielding plate 113-1 has a disc-like shape, and the diameter R1 smaller than the internal diameter of the vacuum processing chamber 117 as described in Example 3 so that the gap from the wall surface of the vacuum processing chamber 117 is formed as an opening. The first shielding plate 113-1 is held by three or more dielectric holders 130 disposed on the second shielding plate 114 similar to the structure as described in Example 3.

The third shielding plate of the example is formed by combining the shielding plate 115 having the height h₄ as described in Example 2 and the shielding plate 115-1 having the height h₃ as described in Example 3. A gap d₅ is formed between the shielding plate 115 and the first shielding plate 113-1, and a gap d₄ is formed between the shielding plate 115-1 and the second shielding plate 114. The shielding plate 115 with the diameter smaller than that of the shielding plate 115-1 is mounted on the second shielding plate 114, and the shielding plate 115-1 with the diameter larger than that of the shielding plate 115 is integrally formed with the first shielding plate 113.

As the shielding section 112-3 is structured as described in the example referring to FIG. 5, the effect of preventing plasma diffusion between the first area 118 and the second area 119 inside the vacuum processing chamber 117 becomes higher than the effect derived from the structures as described in Examples 1 to 3. When plasma is generated in the first area 118 or the second area 119, generation of non-stationary discharge in the other area can be suppressed. Each of the areas where plasma is stably generated can be significantly enlarged as described in Example 1 referring to FIG. 10B.

The similar effect to those described in the second and third Examples can be derived from the example.

### Example 5

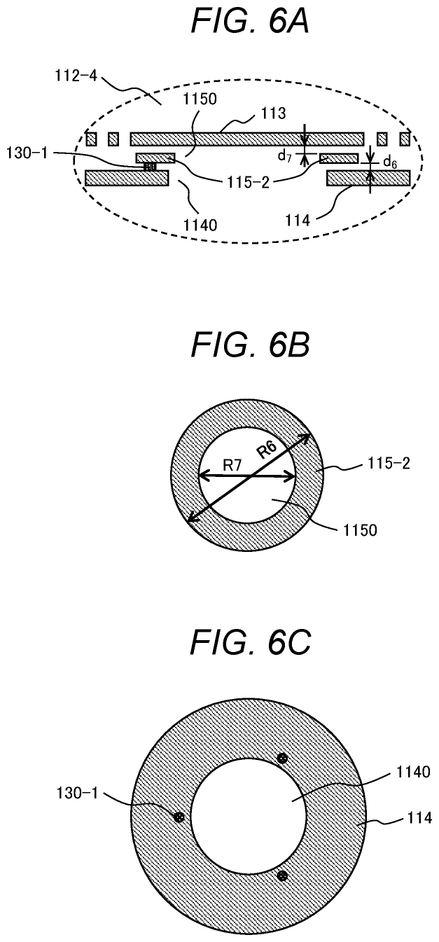

FIG. 6A is a front view representing an example of a shielding section 112-4 according to Example 5 of the present invention. Structures of the example except the shielding section 112-4 are the same as those described in Example 1 referring to FIG. 1, and explanations thereof, thus will be omitted.

The shielding section 112-4 of the example is formed by replacing the third shielding plate 115 of the shielding section 112 of Example 1 with the third shielding plate 115-2. The first shielding plate 113 and the second shielding plate 114 of the example are the same as those described in Example 1, and detailed explanations thereof, thus will be omitted.

The third shielding plate 115-2 of the example has a cylindrical shape with external diameter of R6, and internal diameter R7, and has a gap d₇ formed from the first shielding plate 113, and a gap d₆ formed from the second shielding plate 114, respectively. The third shielding plate 115-2 is held by three or more dielectric holders 130-1 disposed on the second shielding plate 114 as illustrated in FIG. 6C.

A diameter R7 of an opening 1150 of the third shielding plate 115-2 as illustrated in FIG. 6B is set to be the same as or smaller than the diameter R4 (see FIG. 2D) of the opening 1140 of the second shielding plate 114.

In the shielding section 112-4 structured as described above, the third shielding plate 115-2 is located to cross the arbitrary line formed by connecting the first area 118 above the first shielding plate 113-1 and the second area 119 below the second shielding plate 114 through the opening formed in the first shielding plate 113-1, and the opening 1140 formed in the second shielding plate 114. This makes it possible to prevent diffusion of plasma between the first area 118 and the second area 119.

According to the example, upon discharge under the condition for generating plasma in the second area 119 inside the vacuum processing chamber 117, the third shielding plate 115-2 suppresses diffusion of plasma from the second area 119 to the first area 118. As a result, generation of non-stationary discharge in the first area 118 is suppressed to significantly enlarge the stable plasma forming region in the first area 118 and the second area 119, resulting in the similar effects to those described in Example 1.

### Example 6

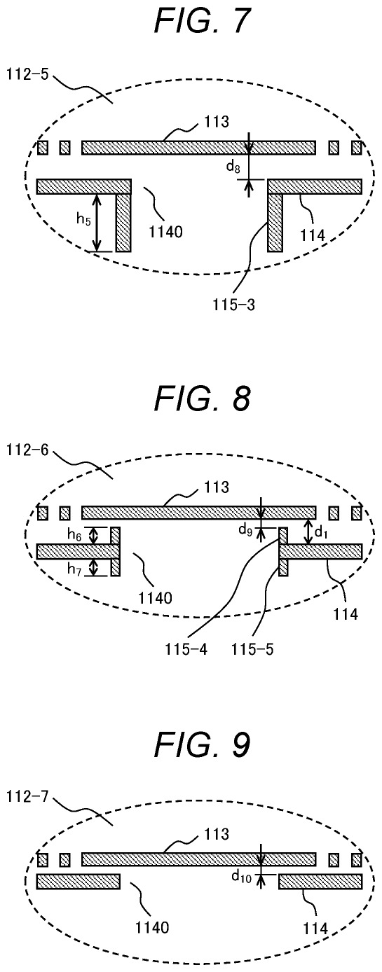

FIG. 7 is a front view representing an example of a shielding section 112-5 according to Example 6 of the present invention. Structures of the example except the shielding section 112-5 are the same as those described in Example 1 referring to FIG. 1, and explanations thereof, thus will be omitted.

The shielding section 112-5 of the example is formed by mounting the cylindrical third shielding plate 115-3 with height h₅ onto the second shielding plate 114 at the side of the second area 119 opposite to the first shielding plate 113 in place of the third shielding plate 115 of the shielding section 112 according to Example 1.

In the example, the internal diameter of the shielding plate 115-3 is set to be the same as that of the opening 1140 formed in the second shielding plate 114. A distance d₈ between the first shielding plate 113 and the second shielding plate 114 is set to be the same as or smaller than the distance d₁ between the first shielding plate 113 and the second shielding plate 114 as described in Example 1 referring to FIG. 2A. In order to secure the plasma diffusion prevention effect between the first area 118 and the second area 119, the height h₅ of the third shielding plate 115-3 is set to be higher than the height h₁ of the third shielding plate 115 of Example 1.

In the shielding section 112-5 structured as described above, the third shielding plate 115-3 is located to cross the arbitrary line formed by connecting the first area 118 above the first shielding plate 113 and the second area 119 outside the third shielding plate 115-3 and below the second shielding plate 114 through the opening 1130 formed in the first shielding plate 113, and the opening 1140 formed in the second shielding plate 114. This makes it possible to prevent diffusion of plasma between the first area 118 and the second area 119.

According to the example, the third shielding plate 115 as described in Example 1 is not disposed between the first shielding plate 113 and the second shielding plate 114. This makes radical transport efficiency from plasma generated in the first area 118 to the second area 119 higher compared with Example 1. In each of the first area 118 and the second area 119, the region where plasma is stably generated can be significantly enlarged as described in Example 1. This makes it possible to provide the effect similar to the one as described in Example 1.

### Example 7

FIG. 8 is a front view representing an example of a shielding section 112-6 according to Example 7 of the present invention. Structures of the example except the shielding section 112-6 of the example are the same as those described in Example 1 referring to FIG. 1, and explanations thereof, thus will be omitted.

The shielding section 112-6 of the example includes the third shielding plate which is formed by combining the cylindrical shielding plate 115-4 with height h 6 corresponding to the third shielding plate 115 of the shielding section 112 according to Example 1, and a shielding plate 115-5 with height h 7 corresponding to the third shielding plate 115-3 as described referring to FIG. 7. The first shielding plate 113 and the second shielding plate 114 are the same as those described in Example 1, and explanations thereof, thus will be omitted.

In the example, each internal diameter of the shielding plates 115-4 and 115-5 is set to be the same as that of the opening 1140 formed in the second shielding plate 114. The distance d₁ between the first shielding plate 113 and the second shielding plate 114 is set to be the same as the distance d₁ between the first shielding plate 113 and the second shielding plate 114 in Example 1 as illustrated in FIG. 2A. The shielding plates 115-4 and 115-5 are integrally formed with the second shielding plate 114.

In the shielding section 112-6 structured as described above, the third shielding plates 115-4 and 115-5 are located to cross the arbitrary line formed by connecting the first area 118 above the first shielding plate 113 and the second area 119 outside the third shielding plate 115-5 and below the second shielding plate 114 through the opening 1130 formed in the first shielding plate 113-1, and the opening 1140 formed in the second shielding plate 114. This makes it possible to prevent diffusion of plasma between the first area 118 and the second area 119.

In the example, the shielding plates 115-4 and 115-5 are mounted on both sides of the second shielding plate 114. The height h₆ of the shielding plate 115-4 formed on the side closer to the first shielding plate can be set to be lower than the height h₁ of the third shielding plate 115 as described in Example 1. A gap d₉ between the shielding plate 115-4 and the first shielding plate 113 can be made larger than the gap d₁ between the third shielding plate 115 and the first shielding plate 113 as described in Example 1. This makes the radical transport efficiency from plasma generated in the first area 118 to the second area 19 higher compared with Example 1.

In the example, the region where plasma is stably generated in the first area and the second area 119 can be significantly enlarged similar to Example 1. This makes it possible to provide the effect similar to the one as described in Example 1.

### Example 8

FIG. 9 is a front view representing an example of a shielding section 112-7 according to Example 8 of the present invention. Structures of the example except the shielding section 112-7 are the same as those described in Example 1 referring to FIG. 1, and explanations thereof, thus will be omitted.

The shielding section 112-7 of the example is not provided with the third shielding plate as described in Examples 1 to 7. In the example, a distance d₁₀ between the first shielding plate 113 and the second shielding plate 114 is set to be small to prevent diffusion of plasma generated in the first area to the second area 119, and plasma generated in the second area 119 to the first area 118 so that generation of non-stationary discharge is suppressed.

In each of the first area 118 and the second area 119 in the example, the region where plasma is stably generated can be significantly enlarged as described in Example 1. This makes it possible to provide the effect similar to the one as described in Example 1.

The embodiment has been described in detail for readily understanding of the present invention, which is not necessarily limited to the one equipped with all structures as described above. It is possible to replace a part of the structure of one embodiment with the structure of another embodiment. The one embodiment may be provided with an additional structure of another embodiment. It is further possible to add, remove, and replace the other structure to, from and with a part of the structure of the respective embodiments.

### REFERENCE SIGNS LIST

101 . . . magnetron,
104 . . . waveguide,
108 . . . solenoid coil,
111 . . . dielectric window,
112, 112-1, 112-3, 112-3, 112-4, 112-5, 112-6, 112-7 . . . shielding section,
113, 113-1 . . . first shielding plate,
114 . . . second shielding plate,
115, 115-1, 115-2, 115-3, 115-4, 115-5 . . . third shielding plate,
116 . . . sample stage,
117 . . . vacuum processing chamber,
118 . . . first area,
119 . . . second area,
120 . . . control unit,
121 . . . valve,
122 . . . pump,
123 . . . matching unit,
124 . . . radio frequency power supply,
125 . . . sample,
130, 130-1 . . . holder

1. A plasma processing device including a processing chamber in which a sample is plasma processed, a radio frequency power supply for supplying microwave radio frequency power, a magnetic field forming mechanism for forming a magnetic field in the processing chamber, a sample stage on which the sample is placed, a first shielding plate for shielding an ion, and a second shielding plate disposed below the first shielding plate for shielding the ion, the plasma processing device further comprising a shielding unit disposed between the first shielding plate having a first opening and the second shielding plate having a second opening,
wherein the shielding unit is located to shield a line that passes through the first opening and the second opening.

2. The plasma processing device according to claim 1,
wherein the first shielding plate is disposed opposingly to the second shielding plate, and has the first opening located outside a position opposite to the second opening;
the second shielding plate has the second opening formed at its center; and
the shielding unit is formed to have a cylindrical shape.

3. The plasma processing device according to claim 1,
wherein the shielding unit is in contact with the second shielding plate.

4. The plasma processing device according to claim 2,
wherein the shielding unit is in contact with the second shielding plate.

5. The plasma processing device according to claim 1,
wherein the shielding unit is integrally formed with the second shielding plate.

6. The plasma processing device according to claim 2,
wherein the shielding unit is integrally formed with the second shielding plate.

7. The plasma processing device according to claim 1,
wherein the shielding unit is integrally formed with the first shielding plate.

8. The plasma processing device according to claim 1,
wherein the shielding unit includes a part integrally formed with the first shielding plate, and a part integrally formed with the second shielding plate.

9. The plasma processing device according to claim 1,
wherein a dielectric is used as a material for forming the first shielding plate, the second shielding plate, and the shielding unit.

10. The plasma processing device according to claim 4,
wherein a dielectric is used as a material for forming the first shielding plate, the second shielding plate, and the shielding unit.
